(19) United States
(12) Patent Application Publication
(10) Pub. No.: US 2004/0077180 A1
(43) Pub. Date: Apr. 22, 2004

(54) Process and control device for the planarization of a semiconductor sample

(76) Inventor: Michael Sebald, Weisendorf (DE)

Correspondence Address: LERNER AND GREENBERG, P.A., POST OFFICE BOX 2480, HOLLYWOOD, FL, 33022-2480, US

(21) Appl. No.: 10/652,282

(22) Filed: Aug. 29, 2003

(30) Foreign Application Priority Data
Aug. 29, 2002 (DE) 102 40 748.7

(51) Int. Cl. H01L 21/31; H01L 21/469

(52) U.S. Cl. 438/780; 438/781

(57) ABSTRACT

A process for planarizing a surface of a semiconductor sample, in particular of a silicon wafer, includes the steps of applying a coating of a polymer solution having a defined solubility in a solvent to a surface of the semiconductor sample; and removing at least part of the coating of the polymer solution by the solvent. This permits efficient planarization and the process can be performed and controlled by a control device.

### BACKGROUND OF THE INVENTION

Field of the Invention

The invention relates to a process for the planarization of a surface of a semiconductor sample, in particular a silicon wafer.

In the production of semiconductor components, it is necessary to planarize surfaces of semiconductor samples (e.g. a wafer), i.e. a plane is to be produced perpendicular to the main material removal direction or main application direction.

A problem that frequently arises is that an organic bottom antireflective coating (BARC) has to be disposed under a photoresist in lithographic processing of the semiconductor sample. Since the substrate of the BARC is uneven, for example owing to contact holes in silica coatings or other structures, the BARC also does not have a flat surface. During spin-coating, the material furthermore collects in depressions of the topography so that the thickness of the BARC is subject to local differences. The quality of the lithography, such as, for example, structural uniformity or process window, is substantially determined by the uniformity of the thickness of the BARC, so that the effects described are disadvantageous.

In order to solve this problem, a thick organically cross-linkable polymer coating (novolac) is applied, for example, by spin-coating, and the polymer coating is then thermally crosslinked on a hotplate (curing) and then etched back to the desired level (recess etch, for example in an oxygen plasma). This results in a planar surface onto which a BARC coating can be applied.

The fact that the additional etching step gives rise to high costs and leads to a discontinuity in the process sequence is disadvantageous.

### SUMMARY OF THE INVENTION

It is accordingly an object of the invention to provide a process and a control device for the planarization of a semiconductor sample that overcomes the above-mentioned disadvantages of the prior art methods and devices of this general type, by which efficient planarization is permitted.

With the foregoing and other objects in view there is provided, in accordance with the invention, a process for planarizing a surface of a semiconductor sample. The process includes the steps of applying a coating, of a polymer solution having a defined solubility in a solvent, to the surface of the semiconductor sample, and removing at least part of the coating of the polymer solution using the solvent.

First, a coating of a polymer solution is applied to a surface of a semiconductor sample (e.g. wafer), the polymer solution having a defined solubility in a solvent. A part of the coating of the polymer solution is then removed by the solvent. Owing to the defined solubility, it is possible to remove the coating of the polymer solution using the solvent so that no removal by plasma etching is required. The “puddle development process” used here leads to planarization of the surface, the process according to the invention being more economical than an additional plasma etching step, particularly since this development process according to the invention can be carried out in the conventional lithography processes without any interruption.

Advantageously, the polymer solution contains a polymer that forms a coating, in particular a polymer from the novolac group, very particularly a cresol novolac polymer.

It is also advantageous if the polymer solution contains polymers or copolymers soluble in an aqueous alkaline medium, in particular polymers or copolymers of vinyl alcohol, acrylic acid, methacrylic acid or para-hydroxystyrene. It is also advantageous if the polymer solution contains a polymer or copolymer soluble in an organic medium, in particular methyl methacrylate, methyl acrylate or styrene.

It is particularly advantageous if the solvent is in the form of an aqueous alkaline solvent, in particular in the form of a developer. These solvents have a constant removal rate of the polymer coating, so that accurate removal of the coating is possible. An aqueous tetramethylammonium hydroxide solution is particularly advantageous as a developer.

In a further advantageous embodiment of the process according to the invention, the solvent is an aqueous solution containing NaOH, KOH and/or surfactants. It is also advantageous if the solvent contains or entirely formed of gamma-butyrolactone, methoxypropyl acetate, NMP, alcohols and/or ethers.

In an advantageous embodiment of the process according to the invention, cross-linking of the polymer by a thermal step is effected after the removal of material by the solvent. It is also advantageous if, after the removal of material by the solvent, cross-linking of the polymer is effected by a step involving exposure to light. The polymer coating is thus stabilized, so that a subsequent coating can no longer attack the coating.

After removal of the material by the solvent, in particular after cross-linking of the polymer, a bottom antireflective coating (BARC) is advantageously applied to the semiconductor sample.

In a further advantageous embodiment of the process according to the invention, a control device (e.g. a computer) serves for automatic control of the removal of the polymer coating as a function of the time of action of the solvent on the polymer coating. Since the removal rates are known or are easily measurable, the removal of the polymer coating can be controlled in an efficient manner via the time of action. It is particularly advantageous if the control device evaluates a functional relationship of the material removal rate and/or of the startup time of the solvent.

The object is also achieved by a control device by which the procedure for the process according to the invention can be controlled.

Other features which are considered as characteristic for the invention are set forth in the appended claims.

Although the invention is illustrated and described herein as embodied in a process and a control device for the planarization of a semiconductor sample, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, sectional view of a semiconductor sample having applied coatings with an uneven bottom antireflective coating according to the prior art; and

FIGS. 2A-2C are diagrammatic, sectional views showing the process steps of an embodiment of the process according to the invention.

### DESCRIPTION OF THE PREFERRED EMBODIMENTS

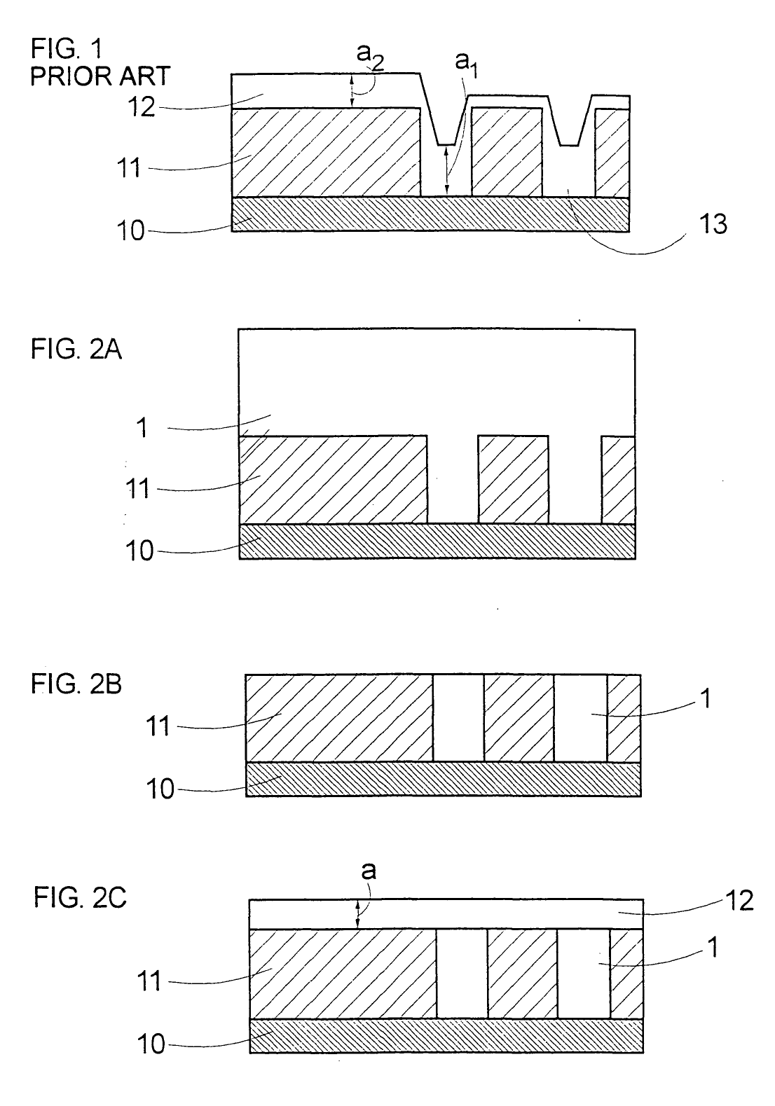

Referring now to the figures of the drawing in detail and first, particularly, to FIG. 1 thereof, there is shown a sectional view through a semiconductor sample 10 having applied coatings 11, 12. The semiconductor sample 10 is in the form of a silicon wafer 10 to which substrate structures 11 have been applied in a manner known per se. The substrate structures 11 have holes 13 (e.g. contact holes in a silica coating).

A bottom antireflective coating (BARC) 12 has been applied over the substrate structure 11 by spin-coating and is intended to be present under a non-illustrative photoresist.

During application of the BARC 12, the material collects in the holes 13 or other depressions, so that an uneven surface results. For processing the semiconductor sample 10 and the substrate structures 11, it is necessary for the BARC 12 to have the same coating thickness ai everywhere. This is not the case in the example according to FIG. 1, since, in the depressions, the BARC has a thickness a₁ that is substantially greater than a thickness a₂ on the substrate structures 11; the coating thickness is nonuniform.

FIGS. 2A to 2C describe an embodiment of the process according to the invention by which the nonuniformity is to be avoided.

A shown in FIG. 2A, a coating of a polymer solution 1 having a defined solubility in a solvent is applied to the substrate structures 11 of the semiconductor sample 10.

In the present case, a cresol novolac is used as the polymer solution. In principle, however, other coating-forming polymers, for example other novolacs, are also suitable. Other soluble, uncross-linked coating-forming polymers, for example polymers or copolymers of vinyl alcohol, acrylic acid, methacrylic acid, para-hydroxystyrene, methyl methacrylate, methyl acrylate or styrene, can also be used.

These polymers have a defined removal rate relative to a solvent (e.g. developer). In the present case, a 2.38% strength solution of tetramethylammonium hydroxide (TMAH) in water is used as a developer. By application of the TMAH solution by a “puddle development” method to the cresol novolac coating 1, the coating is removed down to the level of the substrate structures 11. Here, the material removal rate is 10 nm/s/. Since the material removal rate is constant, the rate of removal can be controlled by time. It should be noted that in some cases the material removal effectively starts only after a startup time of a few seconds (e.g. between 5 and 15 s). These functional dependences can be utilized by an automatic control device (e.g. a computer), by which the removal of the polymer coating 1 can be controlled via the time of action of the solvent.

In a development time of 60 s, less the startup time, exactly 600 nm of the cresol novolac coating 1 are therefore removed. The holes 13 are filled with the cresol novolac.

The result of this defined material removal is shown in FIG. 2B; a planarized surface is present.

The remaining cresol novolac is then thermally cross-linked. Here, this is affected thermally at 230° C. over 60 s on a hotplate. This prevents the cresol novolac coating 1 from undergoing partial dissolution during the subsequent application of the BARC 12.

The BARC 12 which has a uniform coating thickness a everywhere is then applied to the planarized surface. This is shown in FIG. 2C.

A working example of the process according to the invention is described below, reference being made to the figures described above.

Here, a silicon wafer is used as the semiconductor sample 10. A 120 nm fine land-trench structure and an adjacent 5,000 nm land-trench structure in a 500 nm thick silica coating are disposed as the substrate structures 11 on the silicon wafer 10.

The surface of the wafer 10 with the substrate structures 11 is coated with a solution of 25% by weight of cresol novolac in methoxypropyl acetate by of spin-coating (see FIG. 2A). A thermal step at 110° C. over 60 s is carried out on a hotplate. The thickness of the cresol novolac coating 1 is 800 nm, measured relative to unstructured parts of the wafer 10.

The cresol novolac coating 1 has a material removal rate of 14.3 nm/s at a temperature of 23° C. using a 2.38% strength aqueous TMAH solution. The coated wafer 10 is coated in a puddle development chamber with the 2.38% strength TMAH solution. After a time of action of 60 s, washing with water is affected at 1,000 revolutions per minute for 15 s. This is followed by a centrifugal drying step at 4,000 revolutions per minute over 20 s. The cresol novolac coating 1 has thus been removed over the substrate structures 11 in a defined manner. In the case of the material removal, the startup time should be taken into account.

A cross-linking of the cresol novolac still present in depressions, at 230° C. over 90 s on a hotplate, is then effected as preparation for the subsequent application of the BARC (see FIG. 2B).

A BARC 12 is then applied by spin-coating to the wafer 10 thus prepared and subjected to a thermal treatment at 230° C. over 90 s on a hotplate (see FIG. 2C).

For measurement of the result by scanning electron microscopy (SEM), the wafer 10 is broken transversely to the land-trench structures 11 and sputtered with a 0.2 nm thick gold/palladium coating. The scanning electron micrographs show silica structures 11 which are filled with the cross-linked cresol novolac to 30 nm below the upper edge. Above this is a uniform 81 nm thick BARC 12, both above the 120 nm land-trench structure and in the region of the 5,000 nm land-trench structures. Thus, in spite of substrate structures that differ in their size by an order of magnitude, a BARC of uniform thickness has been applied.

When it is carried out, the invention is not restricted to the preferred working examples indicated above. Rather, a number of variants are conceivable which make use of the process according to the invention and the control device according to the invention possible even in embodiments of fundamentally different types.

I claim:

1. A process for planarizing a surface of a semiconductor sample, which comprises the steps of:
applying a coating, of a polymer solution having a defined solubility in a solvent, to the surface of the semiconductor sample; and
removing at least part of the coating of the polymer solution using the solvent.

2. The process according to claim 1, which further comprises forming the polymer solution with a coating-forming polymer.

3. The process according to claim 1, which further comprises forming the polymer solution with a polymer of the novolac group.

4. The process according to claim 1, which further comprises forming the polymer solution with one of polymers and copolymers soluble in an aqueous alkaline medium.

5. The process according to claim 1, which further comprises forming the polymer solution with one of a polymer and a copolymer soluble in an organic medium.

6. The process according to claim 1, which further comprises using an aqueous alkaline solvent as the solvent.

7. The process according to claim 6, which further comprises using aqueous tetramethylammonium hydroxide solution as the solvent.

8. The process according to claim 6, which further comprises forming the solvent as an aqueous solution containing at least one of NaOH, KOH and surfactants.

9. The process according to claim 6, which further comprises forming the solvent from at least one of gamma-butyrolactone, methoxypropyl acetate, NMP, alcohols and ethers.

10. The process according to claim 1, which further comprises subsequently to the removing step, performing a thermal step for cross-linking polymers.

11. The process according to claim 1, which further comprises subsequently to the removing step, exposing polymers to light for cross-linking the polymers.

12. The process according to claim 10, which further comprises subsequently to the cross-linking step, applying a bottom antireflective coating to the semiconductor sample.

13. The process according to claim 1, which further comprises providing a control device for automatically controlling a removal of the polymer coating in dependence on a time of action of the solvent on the coating.

14. The process according to claim 13, which further comprises providing a control device for evaluating at least one of a functional relationship of a material removal rate and a startup time of the solvent.

15. The process according to claim 6, which further comprises providing a developer as the aqueous alkaline solvent.

16. The process according to claim 1, which further comprises forming the polymer solution to contain a cresol novolac polymer.

17. The process according to claim 4, which further comprises forming the polymer solution to contain one of polymers and copolymers of vinyl alcohol, acrylic acid, methacrylic acid or para-hydroxystyrene soluble.

18. The process according to claim 5, which further comprises selecting the polymer solution to contain one of methyl methacrylate, methyl acrylate or styrene.

19. The process according to claim 1, which further comprises providing a silicon wafer as the semiconductor sample.

20. The process according to claim 11, which further comprises subsequently to the cross-linking step, applying a bottom antireflective coating to the semiconductor sample.

21. A control device for controlling a removal of a material, comprising:
means for controlling a removal of at least part of a coating of a polymer solution using a solvent in dependence on a time of action of the solvent on the coating; and
means for evaluating at least one of a functional relationship of a material removal rate and a startup time of the solvent.
